(19) United States
(12) Patent Application Publication
(10) Pub. No.: US 2022/0299863 A1
(43) Pub. Date: Sep. 22, 2022

(54) SYSTEMS AND METHODS FOR DESIGNING PHOTOMASKS

(71) Applicant: YANGTZE MEMORY TECHNOLOGIES CO., LTD., Wuhan (CN)

(72) Inventors: Ming Dong, Wuhan (CN); Lei Zhang, Wuhan (CN)

(73) Assignee: Yangtze Memory Technologies Co., Ltd.

(21) Appl. No.: 17/237,558

(22) Filed: Apr. 22, 2021

Related U.S. Application Data
(63) Continuation of application No. PCT/CN2021/081793, filed on Mar. 19, 2021.

(51) Int. Cl. G03F 1/36

(52) U.S. Cl. CPC G03F 1/36

(57) ABSTRACT

Systems and methods for designing a photomask are disclosed. In an example, a designed pattern is provided. A virtual photomask having a simulated pattern corresponding to the designed pattern is created by at least one processor. The simulated pattern is optimized so that a final pattern to be produced onto a semiconductor substrate converges with the designed pattern. The optimization further includes correcting, by the at least one processor, one or more contours of the simulated pattern so that a geometric difference between the final pattern and the designed pattern meets a predetermined criterion. The correction is based, at least in part, on a model trained from a plurality of training samples.

### CROSS-REFERENCE TO RELATED APPLICATIONS

This application is continuation of International Application No. PCT/CN2021/081793, filed on Mar. 19, 2021, entitled “SYSTEMS AND METHODS FOR DESIGNING PHOTOMASKS,” which is hereby incorporated by reference in its entirety.

### BACKGROUND

The present disclosure relates to systems and methods for designing photomasks, particularly for use in the process of manufacturing semiconductor chips.

The process of manufacturing semiconductor chips involves multiple steps using highly sophisticated apparatuses and technologies, one of which is photolithography. Photolithography allows designed patterns to be transferred to a semiconductor substrate so that the circuit design and transistor layouts are created on the substrate. However, with the continuous decrease of the process nodes (e.g., from 90 nm in 2003 down to 7 nm in 2018), it has become increasingly difficult to transfer the designed patterns to the substrate by photomasks that would yield the same dimensions and contours of the patterns as intended by the designer

### SUMMARY

Systems and methods for designing photomasks are disclosed herein.

In one example, a method for designing a photomask is disclosed. A designed pattern is provided. A virtual photomask having a simulated pattern corresponding to the designed pattern is created by at least one processor. The simulated pattern is optimized so that a final pattern to be produced onto a semiconductor substrate converges with the designed pattern. The optimization further includes correcting, by the at least one processor, one or more contours of the simulated pattern so that a geometric difference between the final pattern and the designed pattern meets a predetermined criterion. The correction is based, at least in part, on a model trained from a plurality of training samples.

In another example, a system for designing a photomask includes a communication interface, a storage, and at least one processor. The communication interface is configured to receive a designed pattern. The at least one processor is configured to create a virtual photomask having a simulated pattern corresponding to the designed pattern, and optimize the simulated pattern so that a final pattern to be produced onto a semiconductor substrate converges with the designed pattern. The storage is configured to store the virtual photomask with the optimized simulated pattern. The optimization is based, at least in part, on a model trained from a plurality of training samples.

In still another example, a tangible computer-readable device has instructions stored thereon that, when executed by at least one computing device, causes the at least one computing device to perform operations. The operations include providing a designed pattern. The operations also include creating, by at least one processor, a virtual photomask having a simulated pattern corresponding to the designed pattern. The operations further include optimizing, by the at least one processor, the simulated pattern so that a final pattern to be produced onto a semiconductor substrate converges with the designed pattern. The optimization further includes correcting, by the at least one processor, one or more contours of the simulated pattern so that a geometric difference between the final pattern and the designed pattern meets a predetermined criterion. The correction is based, at least in part, on a model trained from a plurality of training samples.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a diagram of an exemplary system for fabricating a semiconductor chip, according to some aspects of the present disclosure.

FIG. 2A illustrates an exemplary pattern, according to some aspects of the present disclosure.

FIG. 2B illustrates a pattern produced onto a semiconductor substrate that corresponds to the exemplary pattern in FIG. 2A.

FIG. 2C illustrates an exemplary pattern, according to some aspects of the present disclosure.

FIG. 2D illustrates a pattern produced onto a semiconductor substrate that corresponds to the exemplary pattern in FIG. 2C.

FIG. 3 illustrates a schematic view of a position of an exemplary pattern on a layout, according to some aspects of the present disclosure.

FIG. 4 illustrates a schematic diagram of an exemplary system for designing a photomask, according to some aspects of the present disclosure.

FIG. 5 illustrates a schematic diagram of an exemplary system for training a model for optimizing a simulated pattern, according to some aspects of the present disclosure.

FIG. 6A illustrates an exemplary graph of the result of geometric differences after optimizing a simulated pattern, according to some aspects of the present disclosure.

FIG. 6B illustrates another exemplary graph of the result of geometric differences after optimizing the same simulated pattern as the one used in FIG. 6A, according to some aspects of the present disclosure.

FIG. 7 is a flowchart of an exemplary method for designing a photomask, according to some aspects of the present disclosure.

FIG. 8 is a flowchart of an exemplary method for optimizing the simulated pattern, according to some aspects of the present disclosure.

FIG. 9 illustrates a block diagram of an exemplary computing device, according to some aspects of the present disclosure.

Aspects of the present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

In semiconductor chip fabrication, photolithography is commonly used to create patterns on the surface of a semiconductor substrate. Similar to the patterning process in photography, where light is directed towards photosensitive materials coated on the film, photolithography guides light to photosensitive chemicals disposed on the semiconductor substrate, often in the form of a layer of photoresist, thereby removing certain parts of the photosensitive chemicals and exposing portions of the layer located underneath the photoresist layer. Thereafter, the exposed portions may be etched to create hole structures by dry etching, wet etching, or other suitable etching methods. Then a deposition process (e.g., chemical vapor deposition (CVD), atomic layer deposition (ALD), physical vapor deposition (PVD), electrochemical deposition (ECD), molecular beam epitaxy, or other suitable deposition methods) is carried out to grow, coat, or otherwise transfer a material onto the substrate. The result of this process creates various types of layers or films, such as a blocking layer, a storage lawyer, a semiconductor channel, etc., on the surface of the semiconductor substrate that serve their respective functionalities.

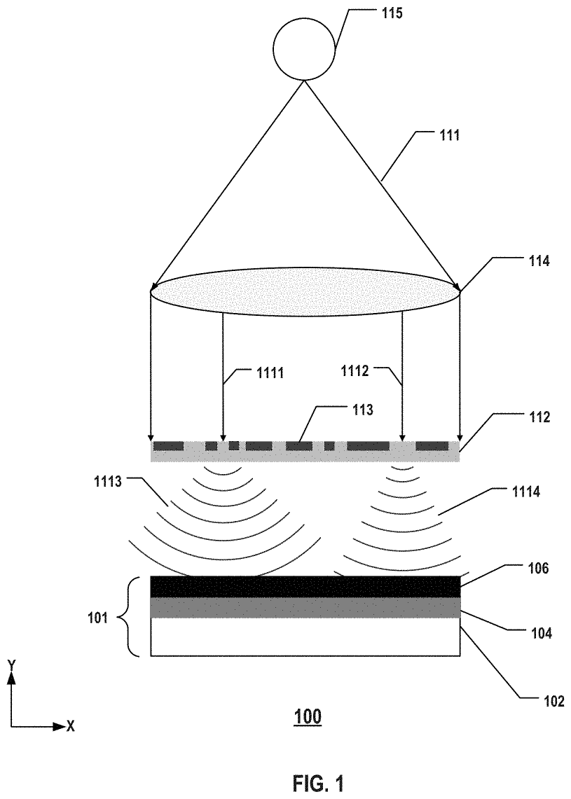

FIG. 1 illustrates a diagram of an exemplary system 100 for fabricating a semiconductor chip, according to some aspects of the present disclosure. The semiconductor chip includes an intermediate structure 101, which may be used to form a 3D NAND memory device, a system-on-chip (SOC), or other integrated circuit (IC) chips. Intermediate structure 101 may have a substrate 102, which may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 102 is a thinned substrate (e.g., a semiconductor layer), which was thinned by grinding, etching, chemical mechanical polishing (CMP), or any combination thereof. It is noted that x and y axes are included in FIG. 1 to further illustrate the spatial relationship of the components in system 100. Substrate 102 may include two lateral surfaces (e.g., a top surface and a bottom surface) extending laterally in the x-direction (i.e., the lateral direction). As used herein, whether one component (e.g., a layer or a device) is “on,” “above,” “below,” or “beneath” another component (e.g., a layer or a device) of a substrate or a system is determined relative to the semiconductor substrate (e.g., substrate 102) in they-direction (i.e., the vertical direction) when the substrate is positioned in the lowest plane of the semiconductor chip in the y-direction. The same notion for describing spatial relationships is applied throughout the present disclosure.

In some aspects consistent with the present disclosure, the semiconductor chip may optionally include a layer 104. Depending on the types of the semiconductor chip, layer 104 may be a dielectric layer, a sacrificial layer, an oxide layer, a conductor layer, an insulation layer, or any other suitable films of materials. Before forming layer 104, substrate 102 may need to be cleaned to remove any contamination present on its surface by, for example, wet chemical treatment. Substrate 102 may be heated to vaporize any moisture thereon, for example, at a temperature of at least 150° C. for 10 to 20 minutes. Subsequently, layer 104 may be formed by deposition (including but not limited to CVD, ALD, PVD, ECD, or any combination thereof) on substrate 102. Layer 104 may be partially exposed for etching after one or more portions of photoresist disposed thereon are removed by photolithography.

According to the present disclosure, a photoresist layer 106 may be formed on substrate 102 or layer 104, depending on the applications of intermediate structure 101. Photoresist layer 106 may include a light-sensitive organic material, such as diazonaphthoquinone (DNQ), methyl methacrylate, or the like. In some implementations, photoresist layer 106 may be deposited on the top surface of layer 104 by spin coating. Spin coating enables photoresist layer 106 to be formed as a thin film with uniform thickness. In other implementations, suitable deposition materials that achieve the same result of uniformity may also be employed to form photoresist layer 106. After formation, photoresist layer 106 may be exposed to light in order to create a pattern thereon. The light may cause chemical reactions in certain exposed areas of photoresist layer 106 so that the exposed portions (for positive photoresist) or the unexposed portions (for negative photoresist) may be soluble in a developer that can carry those portions away from intermediate structure 101, therefore creating a pattern in photoresist layer 106. The layer below photoresist layer 106 may thus be exposed for subsequent etching, deposition, or both to form components of an integrated circuit.

In some aspects of the present disclosure, a photomask 112 may be used to direct light onto the top surface of intermediate structure 101 in a certain pattern, as shown in FIG. 1. The light may be emitted from a light source 115 and become light 111. Light source 115 may employ any light source suitable for photolithography. In some implementations, light source 115 may be a laser light emitter that emits light having a wavelength in the range of ultraviolet (UV), deep ultraviolet (DUV), extreme ultraviolet (EUV), or beyond extreme ultraviolet (BEUV). For example, an EUV light source is typically used in manufacturing semiconductor chips with a process node of 10 nm or below. In some implementations, a condenser lens 114 may be provided between light source 115 and photomask 112 to direct light 111 towards the surface of photomask 112 rather than emit elsewhere, so that energy loss can be reduced. A plurality of parallel light beams directed by condenser lens 114, such as light beams 1111 and 1112, may illuminate onto photomask 112.

Photomask 112 may be a plate made of an opaque material that has certain holes, or transparent or translucent portions that allow light to pass through (hereinafter non-opaque portions). Light may be blocked from passing through by portions of photomask 112 that are neither holes nor transparent/translucent (hereinafter opaque portions), such as portions 113. The composition and materials of photomask 112 may be selected with consideration of the wavelength of light 111 emitted from light source 115. In some implementations, photomask 112 may have a chromium layer on a quartz substrate. In other implementations, photomask 112 may include multiple alternating layers of molybdenum and silicon by reflecting light through these layers. The non-opaque portions may form a layout to direct the projection of light onto the surface of intermediate structure 101, which may be coated with photoresist layer 106, as described above. Although only one plate is shown in FIG. 1 that forms photomask 112, in other implementations consistent with the present disclosure, photomask 112 may include a number of masks, each of which may reproduce a layer. These layouts collectively corresponds to a designed pattern. Such a plurality of photomasks 112 are also known as a photomask set. In other implementations, photomask 112 may include one or more phase-shift masks that utilize the phase change of the light as a result of the different optical thicknesses of the masks.

During the manufacturing process, it is hoped that, by photolithography through photomask 112, the pattern produced onto intermediate structure 101 resembles or equates to the designed pattern, so that the finished semiconductor chip will have layouts matching the original design. However, deviations or distortions of the produced pattern from the designed pattern are often inevitable, such as broader or narrower line widths, protrusions or concaves on a flat side, rounded corners, etc. Such errors may be attributed to diffraction of light 111, process effects, or both. Diffraction occurs when light, propagating as waves, passes through an opening or aperture, which effectively becomes a secondary source of the propagating waves. For example, as shown in FIG. 1, after reaching the openings on photomask 112, light beams 1111 and 1112 are diffracted as light waves 1113 and 1114, respectively. Generally, the smaller the opening, the more quickly the diffracted light diverges and the larger the spot size is on the surface of intermediate structure 101. With respect to process effects, as the process node and the wavelength of light used in the process continue to decrease in recent years, it becomes increasingly difficult for the light to maintain its edge placement integrity. Therefore, compensation techniques are needed to correct these deviations and distortions of the pattern produced on the semiconductor substrate so that the electrical features of the semiconductor devices will not be significantly altered from the designed features.

Consistent with the present disclosure, one of the compensation techniques is known as optical proximity correction (OPC). OPC may be employed to change the layouts on photomask 112 to account for, reduce, or even eliminate the various image errors of the pattern projected onto the semiconductor substrate. In some implementations, OPC may correct these errors by adding polygons, semicircles, or fans, or remove edges or sides of the layouts on photomask 112. Some corrections may be calculated based on a number of parameters, including the wavelength of laser light 111, distances between adjacent features of the layouts (such as lines, rectangles, circles, curves, etc.), heights, widths, and/or diameters of certain shapes, etc. Other corrections may be looked up in a table correlating the input features (that are added to the layouts on photomask 112) and output features (that are reflected in the final produced pattern on the semiconductor substrate), which is compiled from past cases using the same or similar processes.

Usually the correction is a repeated process that takes multiple rounds in order to optimize a photomask that will produce a pattern on the substrate resembling or equating to the designed pattern. Thus, it would be too costly to provide a physical, adjusted photomask after each round of correction and prepare those masks in a trial-and-error type of semiconductor fabrication. Computer-aided design tools may create a virtual photomask that includes a simulated pattern corresponding to the designed pattern, and may also simulate the result of the optimization to find out which corrected virtual photomask has a layout that could be used to produce the final pattern on a semiconductor substrate without significantly altering the intended electrical properties. For example, if the simulated result shows that the distance between two adjacent read/write lines is so close at one place that it may cause a short circuit, the virtual photomask may need further correction. The original pattern may be designed or created by a manufacturer of the semiconductor chip or a designer from a fabless design workshop, using computer software dedicated to the design of IC chips.

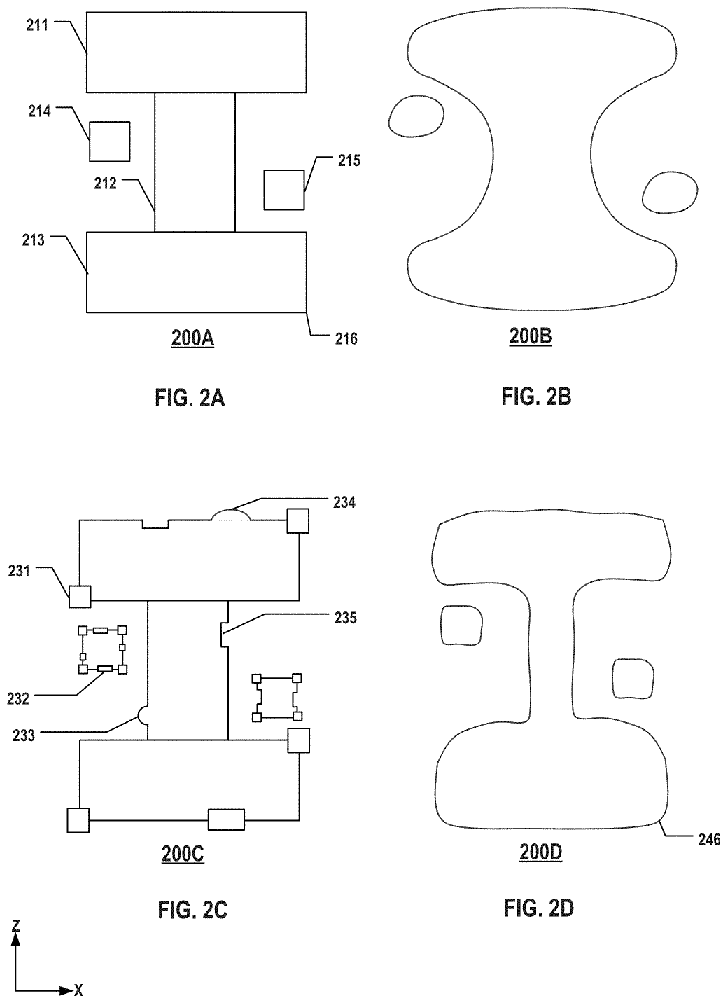

FIG. 2A illustrates an exemplary pattern 200A, according to some aspects of the present disclosure. Pattern 200A may be a portion of a layout drawn by an IC designer using an Electronic Design Automation (EDA) tool. As shown in FIG. 2A, pattern 200A, as well as other patterns described hereinafter, may lie in a horizontal plane defined by the x-direction and the z-direction (which is perpendicular to both the x-direction and the y-direction shown in FIG. 1). As an example, parts 211 to 213 may represent three horizontally positioned electrodes, while parts 214 and 215 may represent two contacts. These parts of pattern 200A have sharp angles and straight contours in the original design. However, when implemented as a layout on a photomask and illuminated with light, these parts might produce onto a semiconductor substrate a final pattern, such as a pattern 200B shown in FIG. 2B, with significant differences from the original. Because of diffraction and process effects, pattern 200B tends to have rounded corners, carved-out sidelines, and a number of other image errors, many of which may render the chip unusable. For example, the distance between parts 211 and 214 becomes so small that they may no longer be electrically separated from each other and may easily get short-circuited.

To remedy these errors, a designer may have to apply various corrections to the layouts on the photomask, which are known as OPC. In some implementations, such applications may be carried out by a processor with help from computer-aided design software. FIG. 2C illustrates another exemplary pattern 200C, according to some implementations of the present disclosure. Pattern 200C may be a simulated pattern corresponding to designed pattern 200A but have been optimized. The optimization may include correction to the contours of pattern 200A. For example, a small polygon may be added to one or more of the parts in pattern 200A, such as a square 231 to part 211, a rectangle 232 to part 214, etc. A curved shape may also be added to one or more of the parts in pattern 200A, such as a semi-circle 233 to part 212, a fan 234 to part 211, etc. Further, a portion of the parts may be carved out, such as concave 235 from part 212, etc. It is noted that the shapes applied when making the correction are not limited to the above-enumerated examples. A person of skill in the art may develop other regular or irregular shapes to achieve the same purpose of optimizing simulated pattern 200C so that the geometric difference between the final pattern to be produced onto the semiconductor substrate and the designed pattern meets a predetermined criterion, which will be discussed later. Such corrections, if applied without reference to a machine-learning model, are referred to as normal OPC in the present disclosure. In contrast, corrections with reference to a machine-learning model are referred to as machine learning-based OPC in the present disclosure.

FIG. 2D illustrates a pattern 200D produced onto a semiconductor substrate that corresponds to pattern 200C in FIG. 2C. As compared to pattern 200B, pattern 200D produced from optimized pattern 200C has contours that more closely resemble the original design, namely, pattern 200A, and thus pattern 200D converges with pattern 200A. Thus, the layouts of the semiconductor substrate can be formed with less alteration of electrical features by using a photomask imprinted with optimized pattern 200C.

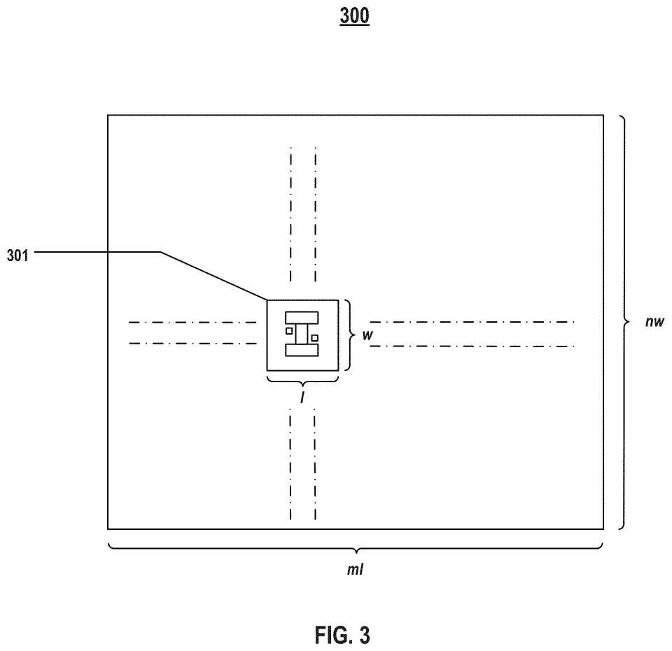

The simulated pattern optimized by the systems and methods according to the present disclosure may correspond to the entire layout of the designed pattern or, alternatively, a portion of the designed pattern. FIG. 3 illustrates a schematic view of a position of an exemplary pattern 301, according to some aspects of the present disclosure. Pattern 301 may only be a portion of the entire layout 300 of the designed pattern, occupying an area with a length/and a width w. In the implementations shown in FIG. 3, the total surface area of the layout may be equally divided into m×n units of patterns, each of which has the same unit area as pattern 301, though the patterns contained therein may vary among themselves. In other implementations, the divided patterns may not be rectangular in shape, which can be adjusted according to the compatibility of the application carrying out the optimization. In yet other implementations, the layout may not be equally divided. For example, the area with denser components, such as those located towards the peripheral of layout 300, may be divided into units with a smaller unit area. As a result, the number of features in those patterns would be comparable to that in patterns with larger unit area but sparser components. In this way, the optimization of each divided pattern could have comparable processing time, therefore reducing the idling time of processors when those patterns are processed parallelly by multiple processor cores.

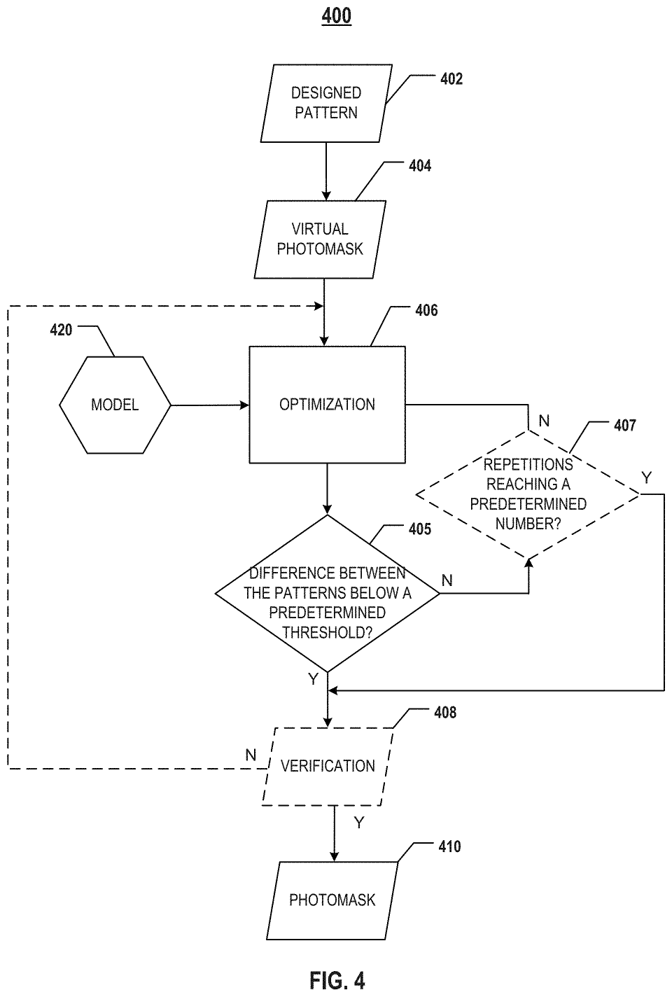

FIG. 4 illustrates a schematic diagram of an exemplary system 400 for designing a photomask, according to some aspects of the present disclosure. System 400 may include at least one processor that implements the various functions disclosed herein for designing a photomask to be used for etching a semiconductor substrate, such as creation of a virtual photomask having a simulated pattern, optimization of the simulated pattern, etc. The processor may be a processing device that includes one or more general processing devices, such as a microprocessor, a central processing unit (CPU), a graphics processing unit (GPU), and the like. More specifically, the processor may be a complex instruction set computing (CISC) microprocessor, a reduced instruction set computing (RISC) microprocessor, a very long instruction word (VLIW) microprocessor, a processor running other instruction sets, or a processor that runs a combination of instruction sets. The processor may also be one or more dedicated processing devices such as application specific integrated circuits (ASICs), field programmable gate arrays (FPGAs), digital signal processors (DSPs), system-on-chip (SoCs), and the like. The processor may be configured as a separate processor module dedicated to performing optimization of the simulated pattern on the virtual photomask. Alternatively, the processor may be configured as a shared processor module for performing other functions. The processor may be communicatively coupled to other components of a computing device, such as a memory or a storage, and configured to execute the computer-executable instructions stored thereon.

In some implementations, system 400 may also include a light source for emitting light through the photomask and onto the semiconductor substrate. The light source may be a laser emitter, such as an excimer laser, that emits light having a wavelength in the range of UV, DUV, EUV, or BEUV. System 400 may further include various optical components, such as a condenser lens, one or more reflectors, etc., that may guide the propagation of the light emitted from the light source and reduce energy loss.

Consistent with the present disclosure, system 400 may include a communication interface (not shown). The communication interface may receive a pattern 402 in the form of a layout of a semiconductor device, such as a memory, a processor, an SoC, etc. During the fabrication of a semiconductor device, pattern 402 may be designed by a developer outside system 400, transmitted as digital data to system 400, imprinted to a photomask, and transferred to a semiconductor substrate using photolithography. The pattern to be produced onto a semiconductor substrate is a final pattern. Various circuits, structures, and connections can be subsequently formed by etching, deposition, and other available manufacturing processes. In some implementations, a plurality of patterns 402 may be needed for multiple exposure and patterning to create a multi-layer semiconductor device. In other implementations, if the surface area of the semiconductor substrate is too large, the layout of the designed pattern may be divided into various sub-patterns, each of which may be imprinted onto an independent photomask for lithography.

A photomask is used in the process of producing a final pattern by directing light to the desired regions of the substrate. System 400 may be used to design such a photomask. In some implementations, system 400 may create a virtual photomask, such as a virtual photomask 404, with the same or a separate processor as described above. Virtual photomask 404 may include a pattern simulated by system 400 to correspond to pattern 402. At the start of the optimization module 406, the simulated pattern may be identical to pattern 402. In some implementations, system 400 may subsequently run simulated lithography of the semiconductor substrate using virtual photomask 404 with the input of various process parameters. Examples of such parameters may include the type of the light source, wavelength of the light, process node, duration of exposure to the light, pitch between various components, critical dimension, density of components, etc. These parameters would allow system 400 to mimic the real-world fabrication environment and approach the actual result. In this way, a virtual result of the final pattern may be simulated by system 400.

In the unlikely event that the final pattern after the first simulation is identical to pattern 402, system 400 does not need to optimize the simulated pattern on virtual photomask 404, as the intended design of the layout can be produced onto the semiconductor substrate without any deviations or distortions. System 400 may directly store virtual photomask 404 in a storage (not shown). Upon request or when a certain event occurs, system 400 may send virtual photomask 404 along with the simulated pattern thereon to the next stage to prepare a physical photomask 408.

However, most of the time, the final pattern after the first simulation is not identical to pattern 402, and system 400 has to determine whether the differences between the two patterns are small enough so that making a physical photomask from the virtual photomask and using it to transfer a designed pattern to the substrate will not render the final pattern useless due to the defects so caused. According to some aspects consistent with the present disclosure, in this determination process 405, system 400 may compare the geometric difference between the two patterns and determine whether a predetermined criterion is met.

During the determination process, the geometric difference may be calculated in a number of ways. In one example, a plurality of feature spots on the designed pattern, such as corner 216 in FIG. 2A, and their respective corresponding feature spots on the final pattern, such as corner 246 in FIG. 2D, may be selected. Feature spots may be chosen from those spots that are most likely to deviate between the designed pattern and the final pattern. Each feature spot has its own x-z coordinates in the horizontal plane defined by the x-direction and the z-direction (or x-z plane). Each pair of corresponding feature spots may be used to calculate the geometric difference between that pair. Thus, the geometric difference between the pair of corners 216 and 246 may be calculated by measuring the horizontal line distance between them, such as calculating the direct distance between their respective coordinates in the x-z plane. In another example, the geometrical difference may be calculated by comparing the variance in key features of the two patterns. For example, each pattern may have one or more discrete shapes, each of which may have a center of gravity. As shown in FIG. 2A, parts 211, 212, 213, 214, and 215 of the designed pattern 200A, may have their respective centers of gravity. Similarly, their corresponding parts in the final pattern, pattern 200D, as shown in FIG. 2D may also have their respective centers of gravity. The offsets between the centers of gravity of the designed pattern and those of the final pattern may be used, at least as one factor, to determine whether a predetermined criterion for tolerating the deviations or distortions is met.

In the above implementations, if the criterion is satisfied, system 400 deems the designed pattern and the final pattern converge, and virtual photomask 404 may be saved to the storage for subsequent processing; if the criterion is not satisfied, virtual photomask 404 may be subject to an optimization process in optimization module 406 in which one or more contours (including but not limited to the angles, lines, absolute and relative positions of components, sizes, etc.) of the simulated pattern on virtual photomask 404 may be corrected by the processor in system 400, and thus reducing the geometric difference.

In some implementations, the criterion may be that the horizontal line distances of at least a predetermined percentage of pairs of corresponding feature spots do not exceed a predetermined distance. In one example, assuming there are 200 pairs of corresponding feature spots, if at least 75% of the pairs (i.e., 150 pairs) have a horizontal line distance of no more than 10 nm, system 400 deems that the geometrical difference between the designed pattern and the final pattern is below a predetermined threshold, and moves on to prepare a physical photomask based on the result of the last round of optimization (including the virtual photomask having the optimized simulated design). Subsequently the physical photomask may be used to produce a pattern on the semiconductor substrate by photolithography technologies.

According to certain aspects consistent with the present disclosure, the predetermined percentage of pairs of corresponding feature spots may be set at a value so that the on-target pairs (that is, pairs with a horizontal line distance not exceeding the predetermined distance) are equal to or more than the off-target pairs (that is, pairs with a horizontal line distance exceeding the same predetermined distance). The higher the percentage means the closer the final pattern is to the designed pattern, which is desired as it means less deviations or distortions from the designed pattern. Thus, the predetermined percentage may be between 50% and 100%, inclusive.

According to certain aspects consistent with the present disclosure, the predetermined distance may be set with reference to the wavelength of the light source, which may affect the selection of the photomask and the ability to maintain the edge placement integrity of the light. Moreover, the diffraction that causes deviations or distortions of the final pattern is also related to the wavelength. The resolution of system 400 is limited by diffraction to the ratio of the wavelength of the waves to the aperture width. Therefore, to diminish the impact of diffraction-caused image errors, the predetermined distance that sets apart on-target pairs and off-target pairs of corresponding feature spots may be set to be equal to or less than half of the wavelength of the light source. For example, when the light source is an EUV having a wavelength of 13.5 nm, the predetermined distance may be set to be 6.25 nm or lower. In other aspects consistent with the present disclosure, depending on the different process nodes, the predetermined distance may be a value selected from the group consisting of 10 nm, 9 nm, 8 nm, 7 nm, 6 nm, 5 nm, 4 nm, 3 nm, 2 nm, 1 nm, 0.9 nm, 0.8 nm, 0.7 nm, 0.6 nm, 0.5 nm, 0.4 nm, 0.3 nm, 0.2 nm, and 0.1 nm.

When the predetermined criterion is not satisfied, either because the predetermined percentage is not reached or for some other reason, system 400 may request continuous optimization of the simulated pattern on the virtual photomask to correct the contours of the simulated pattern. Alternatively, the repetition may be requested by the operator of system 400. In some implementations, the correction may be repeated multiple times, and in each iteration, additional changes to the simulated pattern may be applied in consideration of the feedback of the geometric difference from the previous iteration. In one example, assuming again there are 200 pairs of corresponding feature spots, when the horizontal line distance for a certain pair exceeds the mean value of the 200 horizontal line distances by more than three times of the standard deviation (σ), the region on the virtual mask surrounding the feature spot may receive a higher priority to be corrected than pairs that do not exceed the mean value by three σ. In another example, when the horizontal line distances for all adjacent feature spots in a sized area (e.g., an area of 100 nm×100 nm) of the virtual mask exceed the predetermined distance, that area may be flagged as a highly distorted area and receive more intense optimization in the next iteration than other areas in which at least one horizontal line distance is within the predetermined distance.

According to certain aspects consistent with the present disclosure, the optimization, including the correction of the contours of the simulated pattern, may be repeated if the geometric difference does not meet the predetermined criterion. This will ensure that the final pattern has a deviation from the designed pattern that is small enough to fall within a tolerance of the fabrication precision. Nonetheless, in some implementations, optimization module 406 will optionally stop the correction if the geometric difference fails to meet the predetermined criterion after a predetermined number of iterations. To set a maximum number of iterations can save processing time, because the massive number of corrections to the densely distributed patterns often take up a lot of time, sometimes over hours for each iteration. Experience has shown that the predetermined number could be set at any number between 2 and 20, inclusive. Thus, as shown in FIG. 4, system 400 may make an optional (illustrated in dotted lines) decision 407 whether the repetitions have reached a predetermined number. If yes, system 400 will stop the correction and wrap up the optimization, so that the manufacturing process may move on to make a physical photomask; if no, system 400 will continue to optimize the simulated pattern on the virtual photomask until either the predetermined criterion is satisfied, or the predetermined number of iterations is met.

In some implementations, when the pattern to be simulated only accounts for a portion of the entire layout 300 of the designed pattern, as described above in conjunction with FIG. 3, system 400 shown in FIG. 4 may use multiple processor cores to parallelly process (e.g., optimize) each divided pattern on separate virtual photomasks. The multiple processor cores may constitute one processor of system 400. Alternatively, if the number of divided patterns exceeds the total number of processor cores available in system 400, some or all of them may be serially processed (optimized).

In some implementations, system 400 may have an input device (not shown) that allows the operator to enter, adjust, or delete the parameters related to the repetition of the optimization process. For example, the operator may set the predetermined percentage, the predetermined distance, the predetermined number of iterations, etc., through the input device. Therefore, the predetermined criterion for repeating the optimization may be altered before, in the middle of, or after the photomask design process, thus allowing systems according to these implementations to offer more flexibility than systems without the ability to make such changes. In another example, system 400 may be pre-installed with the various parameters for determining the repetition of the optimization process so that the simulation will not be interrupted midway once it gets started.

In accordance with certain aspects of the present disclosure, system 400 may utilize a model 420 for correcting the contours of the simulated pattern on the virtual photomask. Model 420 may be a machine learning model run by a computing device, which can either be device-independent and separate from system 400 or be integrated with system 400. Model 420 may be a machine learning model trained from a plurality of training samples. Model 420 may be communicatively coupled to optimization module 406.

Various correction rules learned from past sample cases may be applied to the optimization of the patterns on virtual photomask 404, which may have the same or similar components or features as those cases. When model 420 is coupled to optimization module 406, the application may be carried out at optimization module 406 with input of correction rules and/or other parameters from model 420 so that an OPC over the patterns on virtual photomask 404 may be performed. In some implementations, optimization module 406 may determine whether a correction rule learned from one or more past cases can be applied from model 420 to optimize the simulated pattern. The correction rule may be associated with a particular contour (e.g., part 211 in FIG. 2A) so that once system 400 recognize a pattern having the same or similar contour, it may use the same correction method to correct the new contour (e.g., adding a square and a fan to the new contour at the same locations as where square 231 and fan 234 were added to part 211). Thus, if a particular contour found in model 420 matches a contour in the current case under the same fabrication environment (such as using the same wavelength of the light source), optimization module 406 may directly simulate the result of the pattern on virtual photomask 404 by applying the correction rule associated with that particular contour.

Whether two contours match each other may be judged based on measuring the geometric difference between corresponding feature spots of the respective contours. Alternatively, it may be judged based on the line distance of the gravity centers of these two contours. If the geometric difference or the line distance is within a predetermined value, system 400 may determine that a correction rule associated with the contour from one or more past cases can be applied to optimize the simulated pattern. Thus, such a machine learning-based OPC may be employed to obtain the desired simulation result. After this machine learning-based OPC, system 400 may directly use the result as the simulated pattern to produce photomask 410. Alternatively, system 400 may perform one or more iterations of normal OPC (such as that described above in connection with FIGS. 2A to 2D) to fine-tune the contours of the simulated pattern. The added normal OPC may bring the benefit of further narrowing the geometric difference between the designed pattern and the final pattern. Thus, if the geometric difference does not meet a predetermined criterion after application of the correction rule, the iteration may be repeated, as discussed above in conjunction with the determination process 405.

In contrast, if, after optimization module 406 makes the determination, there are no correction rules from model 420 that can be referenced to the current case, system 400 may run the optimization module 406 to perform one or more iterations of normal OPC, without reference to the correction rules from model 420, to identify the right stage when the final pattern converges with the designed pattern. The iteration may be repeated if the geometric difference between the designed pattern and the final pattern does not meet the predetermined criterion after application of the correction rule, as discussed above in conjunction with the determination process 405.

In accordance with certain aspects of the present disclosure, optimization module 406 may first search contours from model 420 to determine whether a correction rule learned from one or more past cases can be applied to the optimization of the simulated pattern. If the determination returns a positive answer, meaning that a contour from a past case matches that of the current case, optimization module 406 may solely run a machine learning-based OPC to obtain an optimized pattern. If the determination returns a negative answer, meaning that no contours from past cases match that of the current case, optimization module 406 may turn to normal OPC to optimize a pattern, which may run one or more iterations. Therefore, the present disclosure using model 420 may significantly decrease the number of iterations in the optimization process needed for the two patterns to converge, as it can directly tell system 400 the best correction that fits a previously trained pattern and get rid of the need to try and err repeatedly for reaching the same result.

As described above in conjunction with FIG. 3, according to some aspects of the present disclosure, the pattern being optimized at one given time by optimization module 406 may only constitute a portion of the entire layout of the pattern instead of the entire layout. The entire layout can be divided into multiple portions that can be optimized separately and thereafter assembled to form a complete pattern. Such optimization may be carried out sequentially, parallelly, or in a hybrid mode (containing both sequential and parallel processing of multiple pattern portions) by the one or more processors of system 400. Some portions may be optimized by machine learning OPC, while others may be optimized by normal OPC. In such implementations, system 400 may optionally include a verification module 408 that checks whether the assembled complete pattern would generate a final pattern that converges with the designed pattern. Verification module 408 may assemble the separately optimized pattern portions into a full pattern with reference to the algorithm that breaks the designed pattern into multiple smaller portions before being input into optimization module 406. Alternatively, the assembly may be carried out in optimization module 406. Subsequently, verification module 408 may use a similar method as those described in conjunction with determination process 405 (e.g., geometric difference) to verify whether the differences between the designed pattern and the final pattern to be generated by the simulated pattern may satisfy a predetermined design tolerance (e.g., with negligible or tolerable defects in semiconductor fabrication). The predetermined design tolerance may be a percent of selected feature spots in the final pattern that deviate from their corresponding feature spots in the designed pattern by a distance over a predetermined value (e.g., 5 nm, 4 nm, 3 nm, 2 nm, 1 nm, 0.9 nm, 0.8 nm, 0.7 nm, 0.6 nm, 0.5 nm, 0.4 nm, 0.3 nm, 0.2 nm, and 0.1 nm). If so, verification module 408 may pass the complete simulated pattern to the next stage to produce photomask 410 with imprinted layouts that correspond to the simulated pattern. Otherwise, verification module 408 may return the process to the start of the optimization, as shown in FIG. 4.

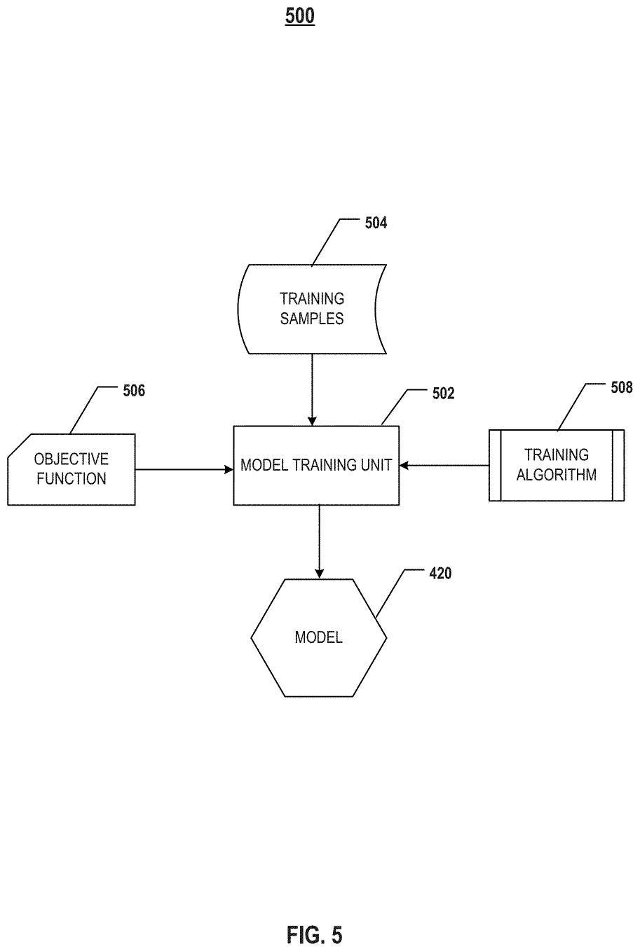

FIG. 5 illustrates a schematic diagram of an exemplary system 500 for training model 420 for optimizing a simulated pattern, according to some aspects of the present disclosure. System 500 may include a plurality of functional units and modules implemented by at least one processor. In some implementations, system 500 may include a model training unit 502, which can train model 420 for correcting the contours of the simulated pattern, over a set of training samples 504 (including past simulated patterns) based on an objective function 506 (also known as a loss function) using a training algorithm 508. More specifically, model 420 may be able to classify what types of adjustment is suitable for the simulated pattern. Model 420 may include a classification model, such as k-nearest neighbors (KNN), convolutional neural networks (CNN), case-based reasoning, decision tree, naive Bayes, artificial neural networks (ANN), logistic regression, Fisher's linear discriminant, support vector machine (SVM), or perceptron.

Training samples 504 may come from past cases of photomask design in which an optimization process has been carried out. These cases represent a treasure trove of all kinds of adjustments made according to different types of components or features of a layout and under various working environment (as defined by multiple process parameters, such as type of the light source, the wavelength of the light, process node, duration of exposure to the light, pitch between various components, critical dimension, density of components, etc.). Each photomask design may be manually, automatically, or semi-automatically labeled with one of multiple predetermined categories each corresponding to a general type of parts or components, such as electrodes, contacts, etc., and/or a process parameter. These types of parts or components may further be broken down according to different shapes, such as round, rectangular, diamond, etc.

In some implementations, model 420 may include one or more parameters (e.g., the kin KNN) that can be jointly adjusted by model training unit 502 when being fed with training samples 504. Model training unit 502 can jointly adjust the parameters of model 420 to minimize objective function 506 over training samples 504 using training algorithm 508. Any suitable objective function 506 and training algorithm 508 can be selected based on the specific type of model 420 to be trained. For example, for a KNN model, a mean square error (MSE)-based objective function may be used by model training unit 502 in combination with a KNN classification training algorithm. It is understood that the training of model 420, e.g., the adjustment of the parameter, may be performed in an iterative manner.

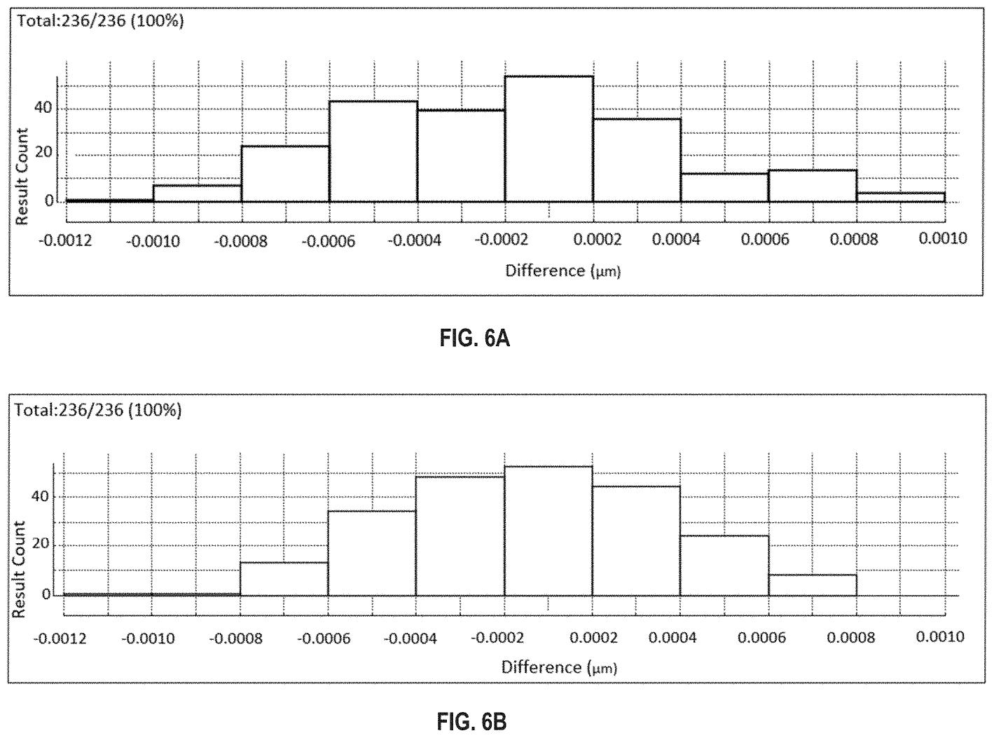

FIG. 6A illustrates an exemplary graph of the result of geometric differences after optimizing a simulated pattern, according to some aspects of the present disclosure. The optimization under FIG. 6A did not use the model trained from a plurality of training samples, and lasted 20 iterations in over 10.5 hours. As shown in FIG. 6A, there are 236 feature spots sampled for the training process, with the largest group of spots having a deviation within a 0.2 nm range. The geometric differences for all but one feature spots fall within a 1 nm range.

FIG. 6B illustrates another exemplary graph of the result of geometric differences after optimizing the same simulated pattern as the one used in FIG. 6A, according to some aspects of the present disclosure. The optimization under FIG. 6B has used the model trained from a plurality of training samples in addition to the normal optimization iterations. The optimization only takes a bit over 3.5 hours, saving two-thirds of the processing time. As shown in FIG. 6B, there are the same number of feature spots (236) sampled for the training process as that in FIG. 6A, with the largest group of spots having a deviation within the 0.2 nm range. The geometric differences for all but one feature spots fall within the 1 nm range. The result shown in FIG. 6B is comparable to that from FIG. 6A but took significantly less time to obtain. Therefore, it is highly advantageous to use the present disclosure to assist the optimization process with a trained machine learning model.

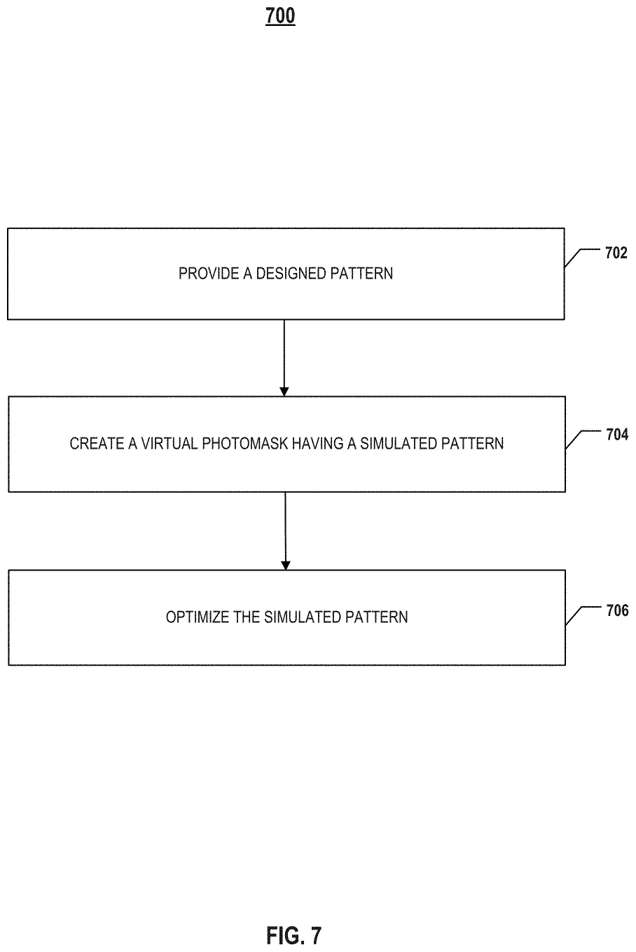

FIG. 7 is a flowchart of an exemplary method 700 for designing a photomask, according to some aspects of the present disclosure. Examples of the device that can perform operations of method 700 may include a computing device depicted in conjunction with the processor and the machine learning model 420 in FIG. 4. It is understood that the operations shown in method 700 are not exhaustive and that other operations can be performed as well before, after, or between any of the illustrated operations. Further, some of the operations may be performed simultaneously, or in a different order than shown in FIG. 7.

As shown in FIG. 7, method 700 starts at operation 702, in which a designed pattern may be provided. The designed pattern may be created by a designer using the same computing device or a different device. By photolithography through a photomask having layouts corresponding to the designed pattern, a final pattern may be produced onto a semiconductor demonstrate. The production may be performed by positioning a photomask between a light source and the substrate so that the light may only illuminate onto the substrate through certain parts of the photomask while being blocked by the others.

Method 700 then proceeds to operation 704, as shown in FIG. 7, where a virtual photomask having a simulated pattern corresponding to the designed pattern may be created by at least one processor similar to the one depicted in conjunction with FIG. 4. In some implementations, the simulated pattern may generally have the same, but not identical, contours as the designed pattern. The simulated pattern may have a plurality of feature spots represented by coordinates in a coordinate system. For example, the coordinate system may be in the same two-dimensional plane as the virtual photomask. The same coordinate system may also apply to the designed pattern and the final pattern in a simulated environment.

Method 700 then proceeds to operation 706, as shown in FIG. 7, where the simulated pattern is optimized by the processor so that the final pattern converges with the designed pattern. During the optimization, one or more contours of the simulated pattern may be corrected by the processor. Then a final pattern may be simulated using parameters that represent the real-world semiconductor manufacturing environment, such that the light source, the wavelength of the light, photomask, process node, semiconductor substrate, time, temperature, and many other parameters may all or partially be taken into consideration.

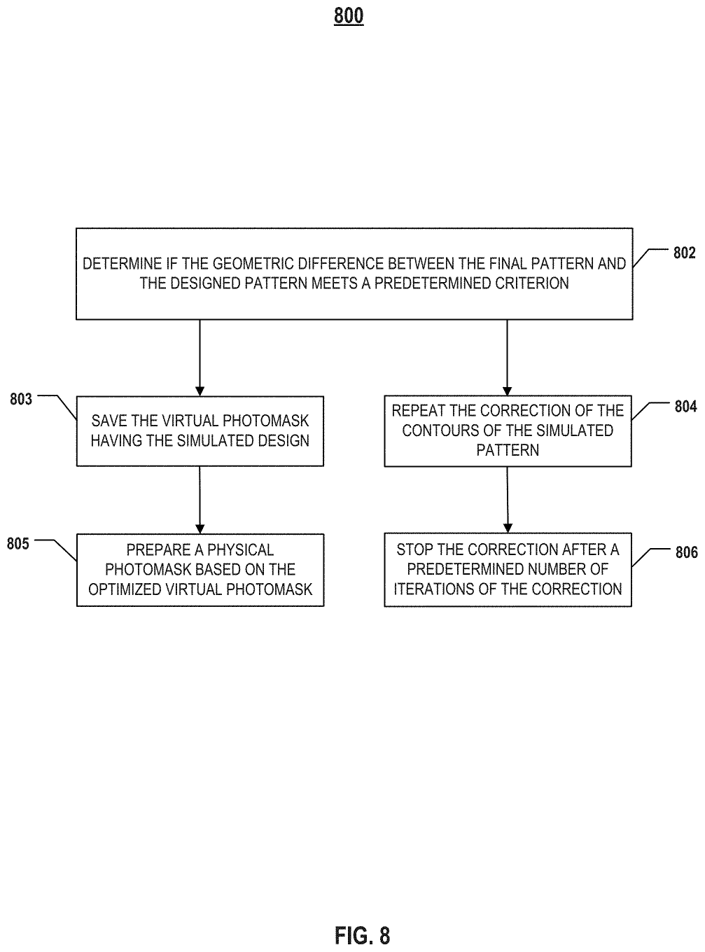

FIG. 8 is a flowchart of an exemplary method 800 for optimizing the simulated pattern, according to some aspects of the present disclosure. According to the present disclosure, a geometric difference between the final pattern and the designed pattern is used to determine whether those two patterns converge in the optimization process. At operation 802, method 800 determined if the geometric difference between the two patterns meets a predetermined criterion. If it meets the predetermined criterion, the optimization is deemed to have achieved the intended result and it moves to operation 803 at which the virtual photomask having the simulated pattern is saved. Thereafter, at operation 805, a physical photomask may be prepared based on the optimized virtual photomask.

On the other hand, if the predetermined criterion is not met, method 800 may proceed to operation 804 continue to optimize the simulated pattern for one or more iterations by, for example, correcting the contours of the simulated pattern. In some implementations, a feedback of the geometric difference from the previous iteration may be considered in the current iteration of correction. Such consideration may be made for each iteration. The correction may be repeated until the geometric difference meets the predetermined criterion. Alternatively, at operation 806, the correction may be stopped if the geometric difference does not meet the predetermined criterion after a predetermined number of iterations of the correction, which may be between 2 and 20, inclusive.

In some implementations, the geometric difference between the designed pattern and the final pattern may be calculated by selecting a plurality of feature spots on the designed pattern and their respective corresponding feature spots on the final pattern, and measuring the horizontal line distance between each pair of corresponding feature spots. The predetermined criterion may be that the horizontal line distance of at least a predetermined percentage of pairs of the corresponding feature spots does not exceed a predetermined distance. The predetermined percentage may be preset either automatically or manually by an operator to be between 50% and 100%, inclusive. The predetermined distance may be preset either automatically or manually by an operator to be equal to or less than half of the wavelength of a light source. For example, the predetermined distance may be a value selected from the group consisting of 10 nm, 9 nm, 8 nm, 7 nm, 6 nm, 5 nm, 4 nm, 3 nm, 2 nm, 1 nm, 0.9 nm, 0.8 nm, 0.7 nm, 0.6 nm, 0.5 nm, 0.4 nm, 0.3 nm, 0.2 nm, and 0.1 nm.

In some implementations, the virtual photomask consistent with the present disclosure may include a plurality of simulated pattern portions. At least two of the simulated pattern portions may be parallelly optimized by the processor described above, which may include a plurality of cores. After optimization, the pattern portions may be assembled to form a complete pattern. The complete pattern may be verified to see whether the differences between the designed pattern and the final pattern (generated as a result of the simulated pattern) are small enough so that making a physical photomask from the virtual photomask and using it to transfer the designed pattern to the substrate will not render the final pattern useless due to the defects so caused.

According to the present disclosure, the optimization of the simulated pattern on the virtual photomask, including the correction of the contours of the simulated pattern, may be based, at least in part, on a model trained from a plurality of training samples. In some implementations, the model is compatible with one or more process parameters selected from the group consisting of the type of the light source, the wavelength of the light, process node, duration of exposure to the light, pitch between various components, critical dimension, density of components, etc. For example, the model may be trained by filtering out one or more of these process parameters from past sample cases, generating a simulated design in consideration of these parameters, comparing the generated design with that in the past cases, and determining whether the generated design converges with that in the past cases. If the two designs converge, it suggests the model trained based on these filtered process parameters may be robust and accurate enough to be applied to the optimization process.

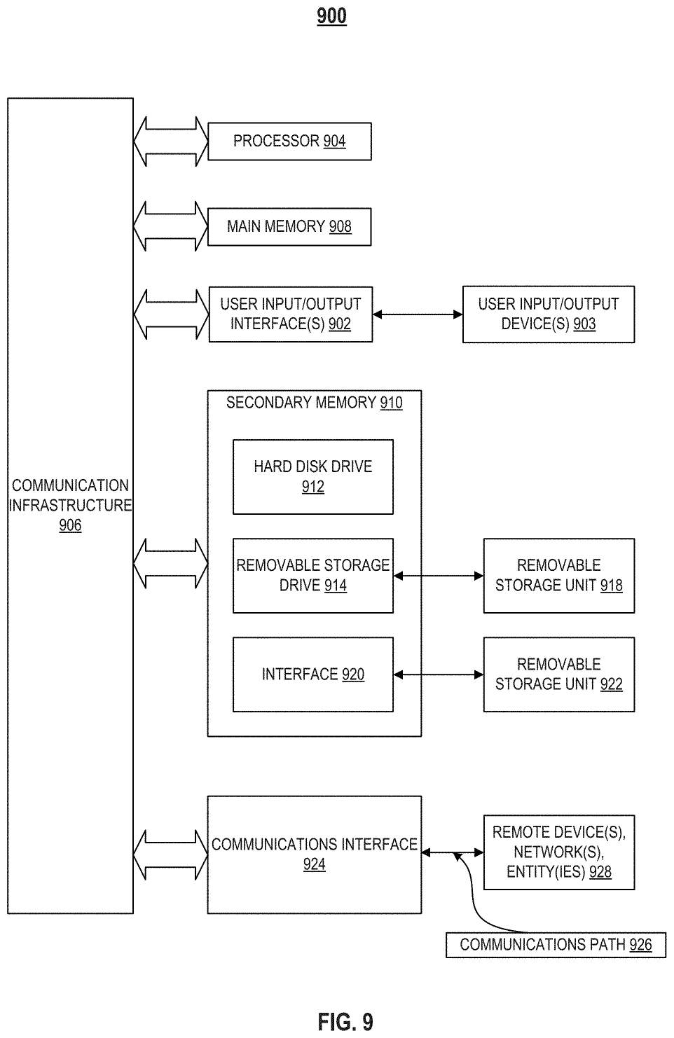

Various aspects according to the present disclosure can be implemented, for example, using one or more computing devices, such as a computing device 900 shown in FIG. 9. One or more computing devices 900 can be an example of the computing device described elsewhere in the present disclosure and can be used, for example, to implement method 700 of FIG. 7 and method 800 of FIG. 8. For example, computing device 900 can perform various functions in designing photomasks, such as creating a virtual photomask, optimizing the simulated pattern, repeating the correction of the contours of the simulated pattern, etc. Computing device 900 can be any computer capable of performing the functions described herein.

Computing device 900 can include one or more processors (also called central processing units, or CPUs), such as a processor 904. Processor 904 is connected to a communication infrastructure or bus 906, according to some embodiments. One or more processors 904 can each be a GPU. In some embodiments, a GPU is a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computing device 900 can also include user input/output device(s) 903, such as monitors, keyboards, pointing devices, etc., which communicate with communication infrastructure or bus 906 through user input/output interface(s) 902.

Computing device 900 can also include a main or primary memory 908, such as random-access memory (RAM). Main memory 908 can include one or more levels of cache. Main memory 908 has stored therein control logic (i.e., computer software) and/or data, according to some embodiments.

Computing device 900 can also include one or more secondary storage devices or memory 910. Secondary memory 910 can include, for example, a hard disk drive 912 and/or a removable storage device or drive 914. Removable storage drive 914 can be a floppy disk drive, a magnetic tape drive, a compact disk drive, an optical storage device, tape backup device, and/or any other storage device/drive.

Removable storage drive 914 can interact with a removable storage unit 918. Removable storage unit 918 includes a computer usable or readable storage device having stored thereon computer software (control logic) and/or data, according to some embodiments. Removable storage unit 918 can be a floppy disk, magnetic tape, compact disk, DVD, optical storage disk, and/any other computer data storage device. Removable storage drive 914 can read from and/or writes to removable storage unit 918 in a well-known manner.

According to some embodiments, secondary memory 910 can include other means, instrumentalities or other approaches for allowing computer programs and/or other instructions and/or data to be accessed by computing device 900. Such means, instrumentalities or other approaches may include, for example, a removable storage unit 922 and an interface 920. Examples of removable storage unit 922 and interface 920 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computing device 900 can further include a communication or network interface 924. Communication interface 924 enables computing device 900 to communicate and interact with any combination of remote devices, remote networks, remote entities, etc. (individually and collectively referenced by reference number 928), according to some embodiments. For example, communication interface 924 may allow computing device 900 to communicate with remote devices 928 over communications path 926, which may be wired and/or wireless, and which may include any combination of LANs, WANs, the Internet, etc. Control logic and/or data may be transmitted to and from computing device 900 via communication path 926.

In some implementations, a tangible apparatus or article of manufacture comprising a tangible computer useable or readable medium having control logic (software) stored thereon is also referred to herein as a computer program product or program storage device. This includes, but is not limited to, computing device 900, main memory 908, secondary memory 910, and removable storage units 918 and 922, as well as tangible articles of manufacture embodying any combination of the foregoing. Such control logic, when executed by one or more data processing devices (such as computing device 900), causes such data processing devices to operate as described herein.

Based on the teachings contained in this disclosure, it will be apparent to persons skilled in the relevant art(s) how to make and use aspects of the present disclosure using data processing devices, computer systems and/or computer architectures suitable for carrying out the embodiments disclosed herein. In particular, the present disclosure may operate with software, hardware, and/or operating system implementations other than those described herein.

According to one aspect of the present disclosure, a method for designing a photomask is disclosed. A designed pattern is provided. A virtual photomask having a simulated pattern corresponding to the designed pattern is created by at least one processor. The simulated pattern is optimized so that a final pattern to be produced onto a semiconductor substrate converges with the designed pattern. The optimization further includes correcting, by the at least one processor, one or more contours of the simulated pattern so that a geometric difference between the final pattern and the designed pattern meets a predetermined criterion. The correction is based, at least in part, on a model trained from a plurality of training samples.

In some implementations, the optimization further includes determining whether a correction rule learned from one or more past cases can be applied from the model to the optimization of the simulated pattern. If a correction rule can be applied to the optimization, the optimization further finds in the one or more past cases a particular contour that matches a contour of the designed pattern, and simulates the pattern on the virtual photomask by applying the correction rule associated with the particular contour.

In some implementations, the optimization further includes performing one or more iterations of normal optical proximity correction to the simulated pattern if the geometric difference does not meet the predetermined criterion after application of the correction rule.

In some implementations, the optimization further includes determining whether a correction rule learned from one or more past cases can be applied from the model to the optimization of the simulated pattern. If no correction rules can be applied to the optimization, the optimization performs one or more iterations of normal optical proximity correction to the simulated pattern if the geometric difference does not meet the predetermined criterion after application of the correction rule.

In some implementations, for each iteration of the correction, the feedback of the geometric difference from the previous iteration is considered.

In some implementations, the optimization further includes stopping the correction if the geometric difference does not meet the predetermined criterion after a predetermined number of iterations of the correction, wherein the predetermined number is between 2 and 20, inclusive.

In some implementations, the geometric difference is calculated by selecting a plurality of feature spots on the designed pattern and their respective corresponding feature spots on the final pattern and measuring a horizontal line distance between each pair of corresponding feature spots.

In some implementations, the predetermined criterion is that the horizontal line distances of at least a predetermined percentage of pairs of the corresponding feature spots do not exceed a predetermined distance.

In some implementations, the predetermined percentage is between 50% and 100%, inclusive.

In some implementations, the predetermined distance is equal to or less than half of a wavelength of a light source.

In some implementations, the model is compatible with one or more process parameters selected from the group consisting of a type of the light source, a wavelength of the light source, process node, duration of exposure to the light source, pitch between various components, critical dimension, and density of components.

In some implementations, the virtual photomask includes a plurality of simulated pattern portions. At least two of the simulated pattern portions are parallelly optimized by the at least one processor. The at least one processor includes a plurality of cores.

In some implementations, the method further includes assembling the plurality of optimized pattern portions into a complete simulated pattern, and verifying whether the differences between the designed pattern and the final pattern to be generated by the complete simulated pattern satisfies a predetermined design tolerance

In some implementations, a physical photomask is prepared based on the optimized virtual photomask.

According to another aspect of the present disclosure, a system for designing a photomask includes a communication interface, a storage, and at least one processor. The communication interface is configured to receive a designed pattern. The at least one processor is configured to create a virtual photomask having a simulated pattern corresponding to the designed pattern, and optimize the simulated pattern so that a final pattern to be produced onto a semiconductor substrate converges with the designed pattern. The storage is configured to store the virtual photomask with the optimized simulated pattern. The optimization is based, at least in part, on a model trained from a plurality of training samples.

In some implementations, the system further includes a light source configured to emit light through the photomask and onto the semiconductor substrate. The light has a wavelength in a range of UV, DUV, EUV, or BEUV.

In some implementations, the virtual photomask with the optimized simulated pattern is used to create a physical photomask.

In some implementations, the at least one processor is further configured to determine whether a correction rule learned from one or more past cases can be applied from the model to the optimization of the simulated pattern. If a correction rule can be applied to the optimization, the at least one processor is further configured to find in the one or more past cases a particular contour that matches a contour of the designed pattern, and to simulate the pattern on the virtual photomask by applying the correction rule associated with the particular contour.

In some implementations, the at least one processor is further configured to perform one or more iterations of normal optical proximity correction to the simulated pattern if the geometric difference does not meet the predetermined criterion after application of the correction rule.

In some implementations, the at least one processor is further configured to determine whether a correction rule learned from one or more past cases can be applied from the model to the optimization of the simulated pattern. If no correction rules can be applied to the optimization, the at least one processor is further configured to perform one or more iterations of normal optical proximity correction to the simulated pattern if the geometric difference does not meet the predetermined criterion after application of the correction rule.

In some implementations, for each iteration of the correction, a feedback of the geometric difference from the previous iteration is considered.

In some implementations, the optimization further includes stopping the correction if the geometric difference does not meet the predetermined criterion after a predetermined number of iterations of the correction, wherein the predetermined number is between 2 and 20, inclusive.

In some implementations, the geometric difference is calculated by selecting a plurality of feature spots on the designed pattern and their respective corresponding feature spots on the final pattern and measuring a horizontal line distance between each pair of corresponding feature spots.

In some implementations, the predetermined criterion is that the horizontal line distances of at least a predetermined percentage of pairs of the corresponding feature spots do not exceed a predetermined distance.

In some implementations, the predetermined percentage is between 50% and 100%, inclusive.

In some implementations, the predetermined distance is equal to or less than half of a wavelength of the light source.

In some implementations, the model is compatible with one or more process parameters selected from the group consisting of a type of the light source, a wavelength of the light, process node, duration of exposure to the light source, pitch between various components, critical dimension, and density of components.

In some implementations, the virtual photomask includes a plurality of simulated pattern portions. At least two of the simulated pattern portions are parallelly optimized by the at least one processor. The at least one processor includes a plurality of cores.

In some implementations, the at least one processor is further configured to assemble the plurality of optimized pattern portions into a complete simulated pattern, and to verify whether the differences between the designed pattern and the final pattern to be generated by the complete simulated pattern satisfies a predetermined design tolerance.

In some implementations, a physical photomask is prepared based on the optimized virtual photomask.

According to still another aspect of the present disclosure, a tangible computer-readable device has instructions stored thereon that, when executed by at least one computing device, causes the at least one computing device to perform operations. The operations include providing a designed pattern. The operations also include creating, by at least one processor, a virtual photomask having a simulated pattern corresponding to the designed pattern. The operations further include optimizing, by the at least one processor, the simulated pattern so that a final pattern to be produced onto a semiconductor substrate converges with the designed pattern. The optimization further includes correcting, by the at least one processor, one or more contours of the simulated pattern so that a geometric difference between the final pattern and the designed pattern meets a predetermined criterion. The correction is based, at least in part, on a model trained from a plurality of training samples.

In some implementations, the tangible computer-readable device further causes the at least one computing device to determine whether a correction rule learned from one or more past cases can be applied from the model to the optimization of the simulated pattern. If a correction rule can be applied to the optimization, the tangible computer-readable device further causes the at least one computing device to find in the one or more past cases a particular contour that matches a contour of the designed pattern, and to simulate the pattern on the virtual photomask by applying the correction rule associated with the particular contour.

In some implementations, the tangible computer-readable device further causes the at least one computing device to perform one or more iterations of normal optical proximity correction to the simulated pattern if the geometric difference does not meet the predetermined criterion after application of the correction rule.

In some implementations, the tangible computer-readable device further causes the at least one computing device to determine whether a correction rule learned from one or more past cases can be applied from the model to the optimization of the simulated pattern. If no correction rules can be applied to the optimization, the tangible computer-readable device further causes the at least one computing device to perform one or more iterations of normal optical proximity correction to the simulated pattern if the geometric difference does not meet the predetermined criterion after application of the correction rule.

In some implementations, for each iteration of the correction, the feedback of the geometric difference from the previous iteration is considered.

In some implementations, the tangible computer-readable device further causes the at least one computing device to stop the correction if the geometric difference does not meet the predetermined criterion after a predetermined number of iterations of the correction, wherein the predetermined number is between 2 and 20, inclusive.

In some implementations, the geometric difference is calculated by selecting a plurality of feature spots on the designed pattern and their respective corresponding feature spots on the final pattern and measuring a horizontal line distance between each pair of corresponding feature spots.

In some implementations, the predetermined criterion is that the horizontal line distances of at least a predetermined percentage of pairs of the corresponding feature spots do not exceed a predetermined distance.

In some implementations, the predetermined percentage is between 50% and 100%, inclusive.

In some implementations, the predetermined distance is equal to or less than half of a wavelength of a light source.

In some implementations, the model is compatible with one or more process parameters selected from the group consisting of a type of the light source, a wavelength of the light source, process node, duration of exposure to the light source, pitch between various components, critical dimension, and density of components.

In some implementations, the virtual photomask includes a plurality of simulated pattern portions. At least two of the simulated pattern portions are parallelly optimized by the at least one processor. The at least one processor includes a plurality of cores.

In some implementations, the tangible computer-readable device further causes the at least one computing device to assemble the plurality of optimized pattern portions into a complete simulated pattern, and to verify whether the differences between the designed pattern and the final pattern to be generated by the complete simulated pattern satisfies a predetermined design tolerance.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A method for designing a photomask, comprising:
providing a designed pattern;
creating, by at least one processor, a virtual photomask having a simulated pattern corresponding to the designed pattern; and
optimizing, by the at least one processor, the simulated pattern so that a final pattern to be produced onto a semiconductor substrate converges with the designed pattern,
wherein the optimization further comprises correcting, by the at least one processor, one or more contours of the simulated pattern so that a geometric difference between the final pattern and the designed pattern meets a predetermined criterion, and
wherein the correction is based, at least in part, on a model trained from a plurality of training samples.

2. The method of claim 1, wherein the optimization further comprises:
determining whether a correction rule learned from one or more past cases can be applied from the model to the optimization of the simulated pattern,
wherein, if a correction rule can be applied to the optimization, finding in the one or more past cases a particular contour that matches a contour of the designed pattern, and simulating the pattern on the virtual photomask by applying the correction rule associated with the particular contour.

3. The method of claim 2, wherein the optimization further comprises:
performing one or more iterations of normal optical proximity correction to the simulated pattern if the geometric difference does not meet the predetermined criterion after application of the correction rule.

4. The method of claim 1, wherein the optimization further comprises:
determining whether a correction rule learned from one or more past cases can be applied from the model to the optimization of the simulated pattern,
wherein, if no correction rules can be applied to the optimization, performing one or more iterations of normal optical proximity correction to the simulated pattern if the geometric difference does not meet the predetermined criterion after application of the correction rule.

5. The method of claim 3, wherein the optimization further comprises:
stopping the correction if the geometric difference does not meet the predetermined criterion after a predetermined number of iterations of the correction,
wherein the predetermined number is between 2 and 20, inclusive.

6. The method of claim 1, wherein the geometric difference is calculated by selecting a plurality of feature spots on the designed pattern and their respective corresponding feature spots on the final pattern and measuring a horizontal line distance between each pair of corresponding feature spots.

7. The method of claim 6, wherein the predetermined criterion is that the horizontal line distances of at least a predetermined percentage of pairs of the corresponding feature spots do not exceed a predetermined distance.

8. The method of claim 7, wherein the predetermined distance is equal to or less than half of a wavelength of a light source.

9. The method of claim 1, wherein the model is compatible with one or more process parameters selected from the group consisting of a type of the light source, a wavelength of the light source, process node, duration of exposure to the light source, pitch between various components, critical dimension, and density of components.

10. The method of claim 1, wherein the virtual photomask comprises a plurality of simulated pattern portions,
wherein at least two of the simulated pattern portions are parallelly optimized by the at least one processor, and
wherein the at least one processor comprises a plurality of cores.

11. The method of claim 10, wherein the method further comprises:
assembling the plurality of optimized pattern portions into a complete simulated pattern, and
verifying whether the differences between the designed pattern and the final pattern to be generated by the complete simulated pattern satisfies a predetermined design tolerance.

12. A system for designing a photomask, comprising:
a communication interface configured to receive a designed pattern; and
at least one processor configured to:
create a virtual photomask having a simulated pattern corresponding to the designed pattern, and
optimize the simulated pattern so that a final pattern to be produced onto a semiconductor substrate converges with the designed pattern; and
a storage configured to store the virtual photomask with the optimized simulated pattern,
wherein the optimization further comprises correcting one or more contours of the simulated pattern so that a geometric difference between the final pattern and the designed pattern meets a predetermined criterion, and
wherein the optimization is based, at least in part, on a model trained from a plurality of training samples.

13. The system of claim 12, further comprising:
a light source configured to emit light through the photomask and onto the semiconductor substrate,
wherein the light has a wavelength in a range of ultraviolet (UV), deep ultraviolet (DUV), extreme ultraviolet (EUV), or beyond extreme ultraviolet (BEUV).

14. The system of claim 12, wherein the at least one processor is further configured to:
determine whether a correction rule learned from one or more past cases can be applied from the model to the optimization of the simulated pattern,
wherein, if a correction rule can be applied to the optimization, find in the one or more past cases a particular contour that matches a contour of the designed pattern, and simulate the pattern on the virtual photomask by applying the correction rule associated with the particular contour.

15. The system of claim 14, wherein the at least one processor is further configured to:
perform one or more iterations of normal optical proximity correction to the simulated pattern if the geometric difference does not meet the predetermined criterion after application of the correction rule.

16. The system of claim 12, wherein the at least one processor is further configured to:
determine whether a correction rule learned from one or more past cases can be applied from the model to the optimization of the simulated pattern,
wherein, if no correction rules can be applied to the optimization, perform one or more iterations of normal optical proximity correction to the simulated pattern if the geometric difference does not meet the predetermined criterion after application of the correction rule.

17. The system of claim 12, wherein the geometric difference is calculated by selecting a plurality of feature spots on the designed pattern and their respective corresponding feature spots on the final pattern and measuring a horizontal line distance between each pair of corresponding feature spots.

18. The system of claim 12, wherein the virtual photomask comprises a plurality of simulated pattern portions,
wherein at least two of the simulated pattern portions are parallelly optimized by the at least one processor, and
wherein the at least one processor comprises a plurality of cores.

19. The system of claim 18, wherein the at least one processor is further configured to:
assemble the plurality of optimized pattern portions into a complete simulated pattern, and
verify whether the differences between the designed pattern and the final pattern to be generated by the complete simulated pattern satisfies a predetermined design tolerance.

20. A tangible computer-readable device having instructions stored thereon that, when executed by at least one computing device, causes the at least one computing device to perform operations comprising:
providing a designed pattern,
creating, by at least one processor, a virtual photomask having a simulated pattern corresponding to the designed pattern; and
optimizing, by the at least one processor, the simulated pattern so that a final pattern to be produced onto a semiconductor substrate converges with the designed pattern,
wherein the optimization further comprises correcting, by the at least one processor, one or more contours of the simulated pattern so that a geometric difference between the final pattern and the designed pattern meets a predetermined criterion, and
wherein the correction is based, at least in part, on a model trained from a plurality of training samples.
